(19) United States
(12) Patent Application Publication
(10) Pub. No.: US 2021/0076547 A1
(43) Pub. Date: Mar. 11, 2021

(54) SHIELDING TAPE FOR ELECTROMAGNETIC WAVE

(71) Applicant: 3M INNOVATIVE PROPERTIES COMPANY, St. Paul, MN (US)

(72) Inventors: Seong-Woo Woo, Gyeonggi-do (KR); Jung-Ju Suh, Seoul (KR)

(21) Appl. No.: 15/733,782

(22) PCT Filed: May 7, 2019
(86) PCT No.: PCT/IB2019/053731

§ 371 Date: Oct. 26, 2020

(30) Foreign Application Priority Data
May 16, 2018 (KR) 10-2018-0056128

(51) Int. Cl. H05K 9/00; C09J 7/29; B32B 3/08; B32B 25/04

(52) U.S. Cl. CPC H05K 9/0088; C09J 7/29; B32B 3/085; B32B 25/04; B32B 2307/212; C09J 2301/16; C09J 2301/302; C09J 2301/314; B32B 2405/00; C09J 2203/318

(57) ABSTRACT

A shielding tape according to an embodiment of the present disclosure includes a plurality of shielding members discrete from one another on a same plane, and, when the shielding tape is stretched in a first direction which is perpendicular to a thickness direction of the shielding tape, a distance between at least a portion of the shielding members increases, and a distance between the other portion of the shielding members is reduced.

### TECHNICAL FIELD

The present disclosure relates to a shielding tape.

### BACKGROUND

As consumers' interests and demands for functions, operation speed, portability, or etc. of electronic devices such as smartphones, tablet personal computers (PCs), or the like are increasing, electronic devices are gradually evolving, focusing on function integration, high-capacity, high speed, or etc.

As a plurality of high-integration semiconductor devices are mounted on a printed circuit board of an electronic device to process high-capacity data rapidly, electro magnetic interference (EMI) inevitably occurs in the electronic device, and, in order to solve this EMI problem, various shielding members for electromagnetic wave such as shielding filters for electromagnetic wave, etc. are developing.

However, as a frequency band of electromagnetic signals used in electronic devices, including smartphones, increases up to a high frequency band of giga hertz (GHz) or higher in recent years, a high frequency noise problem may arise inside electronic devices. Therefore, there may be difficulty in solving the high-frequency noise problem with conventional shielding members for electromagnetic wave.

Accordingly, researches to solve the high-frequency noise problem are ongoing in various fields, and as a part of the researches, a shielding tape provided with a magnetic substance having a good magnetic property in high frequency band has been suggested.

### DETAILED DESCRIPTION OF THE INVENTION

### Technical Objects

Embodiments of the present disclosure provide a shielding tape which is stretchable in a predetermined direction and is contractible to return to its initial position, and can stably maintain a magnetic property during the stretching and contracting process in the predetermined direction.

In addition, embodiments of the present disclosure provide a shielding tape which has a good magnetic property not only in a low frequency band but also in a high frequency band, and can effectively block electromagnetic waves from case where a frequency of electromagnetic waves emitted from an electronic device is low to a case where the frequency is high.

### Technical Solving Means

According to one aspect of the present disclosure, there is provided a shielding tape including a plurality of shielding members discrete from one another on a same plane, wherein, when the shielding tape is stretched in a first direction which is perpendicular to a thickness direction of the shielding tape, a distance between at least a portion of the shielding members increases, and a distance between the other portion of the shielding members is reduced.

### Advantageous Effects

The shielding tape according to embodiments of the present disclosure has effects that the shielding tape is stretchable in a predetermined direction and is contractible to return to its initial position, and can stably maintain a magnetic property during the stretching and contracting process in the predetermined direction.

In addition, the shielding tape according to embodiments of the present disclosure has effects that the shielding tape has a good magnetic property not only in a low frequency band but also in a high frequency band, and can effectively block electromagnetic waves from a case where a frequency of electromagnetic waves emitted from an electronic device is low to a case where the frequency is high.

### BRIEF DESCRIPTION OF THE DRAWINGS

FIG. 1 is a perspective view illustrating a shielding tape according to an embodiment of the present disclosure;

FIG. 2 is an exploded perspective view illustrating the shielding tape according to an embodiment of the present disclosure;

FIG. 3 is a cross-sectional view taken on line A-A of FIG. 1;

FIG. 4 is a top view illustrating an example of a plurality of shielding members of the shielding tape according to an embodiment of the present disclosure;

FIG. 5 is a view illustrating the plurality of shielding members when a tensile force in a predetermined direction is applied to the shielding tape according to an embodiment of the present disclosure;

FIG. 6 is a cross-sectional view illustrating a variation of the plurality of shielding members of the shielding tape according to an embodiment of the present disclosure; and

FIG. 7 is a cross-sectional view illustrating another variation of the plurality of shielding members of the shielding tape according to an embodiment of the present disclosure.

### BEST MODE FOR EMBODYING THE INVENTION

Hereinafter, specific embodiments for embodying the idea of the present disclosure will be described in detail with reference to the accompanying drawings. Herein, it should be noted that the drawings are not drawn at a constant ratio for convenience of explanation. In addition, in explaining the present disclosure, detailed descriptions of well-known configurations or functions will be omitted since they would unnecessarily obscure the subject matters of the present disclosure.

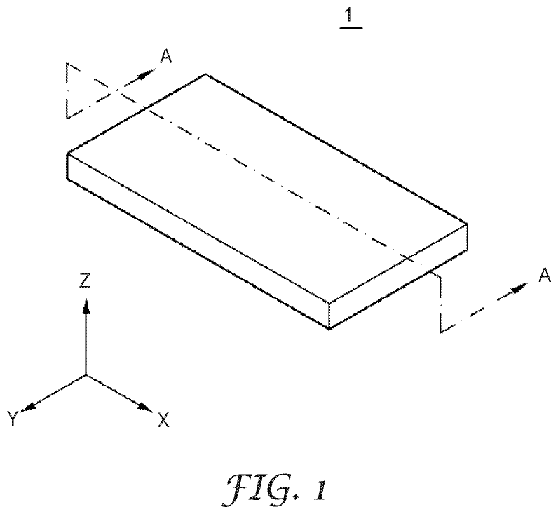

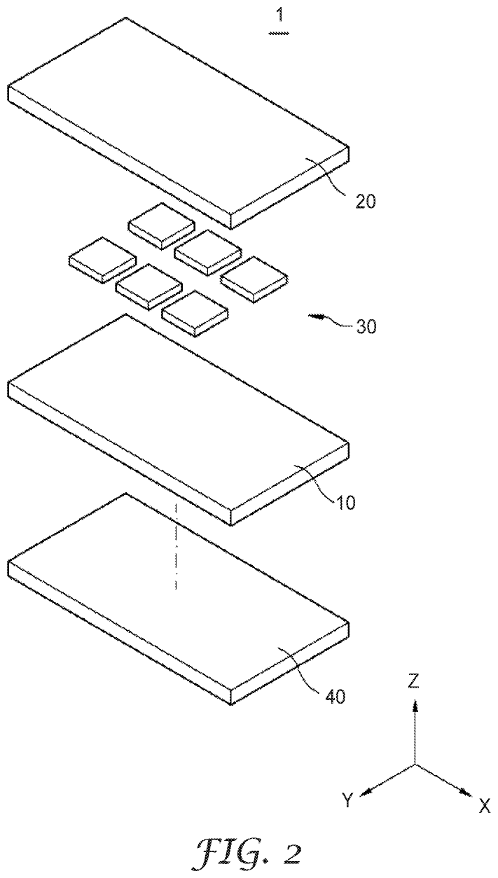

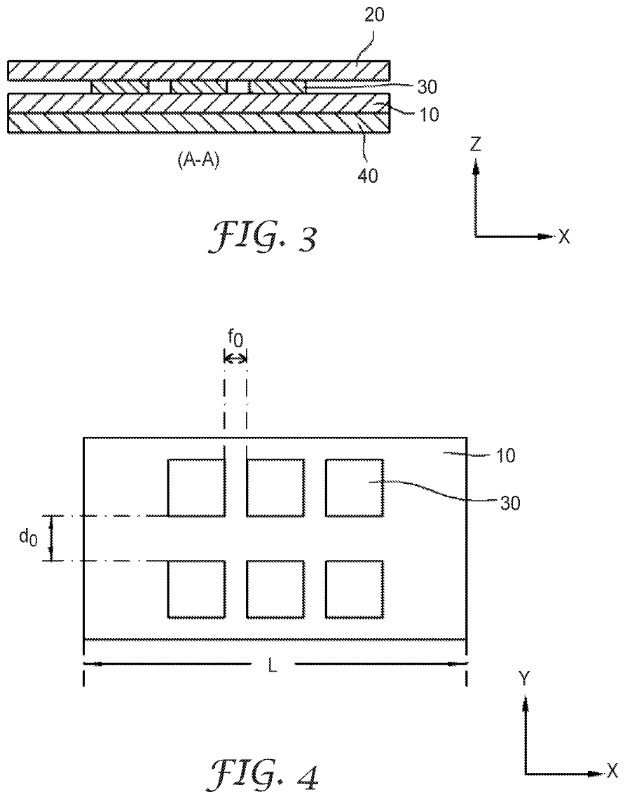

FIG. 1 is a perspective view illustrating a shielding tape according to an embodiment of the present disclosure, FIG. 2 is an exploded perspective view illustrating the shielding tape according to an embodiment, FIG. 3 is a cross-sectional view taken on line A-A of FIG. 1, FIG. 4 is a top view illustrating an example of a plurality of shielding members of the shielding tape according to an embodiment, and FIG. 5 is a view illustrating the plurality of shielding members when a tensile force in a predetermined direction is applied to the shielding tape according to an embodiment.

Referring to FIGS. 1 and 2, the shielding tape 1 according to an embodiment may include a first soft member 10, a second soft member 20, and a plurality of shielding members 30.

The first soft member 10 may provide softness to the shielding tape 1. The first soft member 10 may be formed with a material having stretchable elasticity. For example, the first soft member 10 may be formed with a material including rubber. The first soft member 10 may be configured to be easily in close contact with an electronic device which has a non-even surface that requires the shielding tape 1 to be curved or bent, for example, a wearable device.

The first soft member 10 may provide a restoring force to the shielding tape 1. For example, when the shielding tape 1 is subject to a tensile force in a first direction, the first soft member 10 may be stretched in the first direction, and, when the tensile force for stretching the shielding tape 1 in the first direction is removed, the shieling tape 1 may be contracted in the first direction and may return to its initial position.

Referring to FIG. 2, the first direction may refer to, for example, any one direction that is perpendicular to a thickness direction of the shielding tape 1, and a second direction may refer to another direction that is perpendicular to the thickness direction of the shieling tape 1 and intersects the first direction. For example, the first direction may refer to a length direction of the shielding tape 1, that is, an x-axis direction with reference to FIG. 2, and the second direction may refer to a width direction of the shielding tape 1, that is, a y-axis direction with reference to FIG. 2. However, in the following description, the first direction refers to the length direction of the shielding tape 1, and the second direction refers to the width direction of the shielding tape 1 for convenience of explanation.

When a tensile force is applied to the shielding tape 1 in the length direction, the first soft member 10 may be stretched in the length direction. When the shielding tape 1 is stretched in the length direction, a length of the stretched shielding tape 1 may be a length L₁ (see FIG. 5) in the length direction that falls within 200% of an initial length L₀ (see FIG. 4), for example. When the tensile force for stretching the shielding tape 1 in the length direction is removed, the first soft member 10 may be contracted in the length direction and may return to its initial position. For example, when the tensile force is removed, the shielding tape 1 may have a length in the length direction that falls within 110% of the initial length L₀.

When the shielding tape 1 is stretched in the length direction, the shielding tape 1 stretched in the length direction may have a change in relative permeability that is less than 10% of relative permeability of the shielding tape 1 before it is stretched in the length direction. In other words, the relative permeability of the shielding tape 1 stretched in the length direction is maintained by 90% or higher of the relative permeability of the shielding tape 1 before it is stretched in the length direction, such that a magnetic property (relative permeability) of the shielding tape 1 can be stably maintained during the stretching and contracting process of the shielding tape 1 in the length direction.

The second soft member 20 may face the first soft member 10 and may be arranged in the same space. Bing arranged in the same space may imply that the second soft member 20 and the first soft member 10 are arranged to correspond to each other. The second soft member 20 may provide softness and a restoring force to the shielding tape 1. Herein, the second soft member 20 providing the softness and the restoring force to the shielding tape 1 is substantially the same as the first soft member 10 providing softness and a restoring force to the shielding tape 1, and thus a redundant description is omitted and is replaced with the description presented above.

The plurality of shielding members 30 may be configured to block electromagnetic waves of an electronic device, while maintaining the magnetic property, for example, relative permeability, during the stretching and contracting process of the shielding tape 1 in the length direction. Herein, the relative permeability may be divided into real part permeability and imaginary part permeability. In general, as imaginary part permeability increases, absorption of electromagnetic waves is better. Accordingly, it may be deemed that, as the imaginary part permeability increases, there is a greater shielding effect for electromagnetic wave.

The plurality of shielding members 30 substantially determine the shielding performance of the shielding tape 1 for electromagnetic wave, and the plurality of shielding members 30 may be formed with a soft magnetic metal ribbon including a nanocrystalline alloy to enhance the shielding performance of the shielding tape 1 for electromagnetic wave. Accordingly, the plurality of shielding members 30 may increase the imaginary part permeability indicating an electromagnetic wave absorption phenomenon up to a giga hertz (GHz) band.

Referring to FIGS. 3 to 5, the plurality of shielding members 30 may be discreate from one another on substantially the same plane. The plurality of shielding members 30 may be coupled to at least one of the first soft member 10 and the second soft member 20.

The plurality of shielding members 30 may be spaced apart from one another in the first direction between the first soft member 10 and the second soft member 20. The plurality of shielding members 30 may have a rectangular shape. However, this is merely an example, and the shape of the plurality of shielding members 30 may be changed variously as long as they can be arranged at predetermined intervals on at least one of the first soft member 10 and the second soft member 20.

Referring to FIGS. 4 and 5, the plurality of discrete shielding members 30 may be spaced apart from one another by various distances on substantially the same plane. Referring to FIG. 4, in the shielding tape 1 before the tensile force in the length direction is applied, at least a portion of the plurality of shielding members 30 may be spaced apart from one another by a first distance f₀ in the first direction, and the other portion of the plurality of shielding members 30 may be spaced apart from one another by a second distance d₀ in the second direction which is different from the first direction.

Referring to FIG. 5, for example, when the tensile force for stretching the shielding tape 1 in the first direction is applied, the distance between the at least portion of the shielding members 30 may increase, and the distance between the other portion of the shielding members 30 may be reduced. For example, when the first soft member 10 and the second soft member 20 are stretched in the first direction, the first distance f₀ may increase to a first distance f₁, and the second distance d₀ may be reduced to a second distance d₁. For example, the increase of the first distance f₀ is offset by the reduction of the second distance d₀, such that the relative permeability of the shielding tape 1 can be maintained.

When the tensile force for stretching the shielding tape 1 in the first direction is removed, the first soft member 10 and the second soft member 20 are contracted in the first direction, and the increased first distance f₁ may be reduced, and the reduced second distance d₁ may increase. Accordingly, the relative permeability of the shielding tape 1 can be maintained during the stretching and contracting process of the shielding tape 1.

An adhesive layer 40 may be formed on an outer surface of any one of the first soft member 10 and the second soft member 20. It is illustrated in the drawings that the adhesive layer 40 is formed on the outer surface of the first soft member 10, but this is merely an example. The adhesive layer 40 may be formed on the outer surface of the second soft member 20. The adhesive layer 40 enables the shielding tape 1 to be attached to an electronic device. For example, the adhesive layer 40 may be a layer that is formed with a pressure sensitive adhesive, but this is merely an example, and any adhesive that has predetermined electrical conductivity is applicable as the adhesive layer.

Hereinafter, a maximum shielding frequency of the shielding member 30 will be described.

The maximum shielding frequency of the shielding member 30 refers to a frequency at which the imaginary part permeability of the shielding member 30 increases to the maximum, and may depend on at least one of initial relative permeability of the shielding member 30, a distance between the shielding members 30, and a size of a cross section of the shielding member 30. Herein, the distance between the shielding members 30 may be the first distance f₀ or the second distance d₀, and the size of the cross section of the shielding member 30 refers to a size of a cross section of the shielding member 30 in a parallel direction with the first soft member 10 and the second soft member 20.

Relationships between the initial relative permeability of the shielding member 30, the distance between the shielding members 30, and the size of the cross section of the shielding member 30, and the maximum shielding frequency are shown in table 1 presented below, including values obtained by an experiment:

TABLE 1

| Initial | | | Size of cross | | | |
|---|---|---|---|---|---|---|
| Relative | Distance between | | section of | | Maxim shielding | |
| Permeability | shielding members | | shielding member | | frequency | |
| 100 | 0.1 | um | 10 | um | 29 | MHz |
| | 300 | um | 5,000 | um | 2.9 | GHz |
| 500 | 0.1 | um | 10 | um | 5.82 | MHz |
| | 300 | um | 5,000 | um | 582 | MHz |
| 700 | 0.1 | um | 10 | um | 4.16 | MHz |
| | 300 | um | 5,000 | um | 416 | MHz |
| 1,000 | 0.1 | um | 10 | um | 2.91 | MHz |
| | 300 | um | 5,000 | um | 291 | MHz |
| 5,000 | 0.1 | um | 10 | um | 582 | kHz |
| | 300 | um | 5,000 | um | 58 | MHz |
| 10,000 | 0.1 | um | 10 | um | 291 | kHz |
| | 300 | um | 5,000 | um | 29 | MHz |
| 50,000 | 0.1 | um | 10 | um | 58 | kHz |
| | 300 | um | 5,000 | um | 5.8 | MHz |
| 80,000 | 0.1 | um | 10 | um | 36 | kHz |
| | 300 | um | 5,000 | um | 3.6 | MHz |

Due to the material property of the shielding member 30, the imaginary part permeability of the shielding member 30 is shifted from a low frequency band to a high frequency band. Therefore, when the shielding members 30 have the same size of the cross section, a frequency blocked by the shielding member 30 increases as the distance between the shielding members 30 increases. In addition, as the distance between the shielding members 30 is reduced, the imaginary part permeability of the shielding member 30 is shifted from a high frequency band to a low frequency band. Therefore, as the distance between the shielding members 30 is reduced, the frequency blocked by the shielding member 30 may be reduced.

When the shielding members 30 have the same distance therebetween, the imaginary part permeability of the shielding member 40 is shifted from a low frequency band to a high frequency band as the size of the cross section of the shielding member 30 is reduced. Therefore, as the size of the cross section of the shielding member 30 is reduced, the frequency blocked by the shielding member 30 may increase. In addition, as the size of the cross section of the shielding member 30 increases, the imaginary part permeability of the shielding member 30 is shifted from a high frequency band to a low frequency band. Therefore, as the size of the cross section of the shielding member 30 increases, the frequency blocked by the shielding member 30 may be reduced.

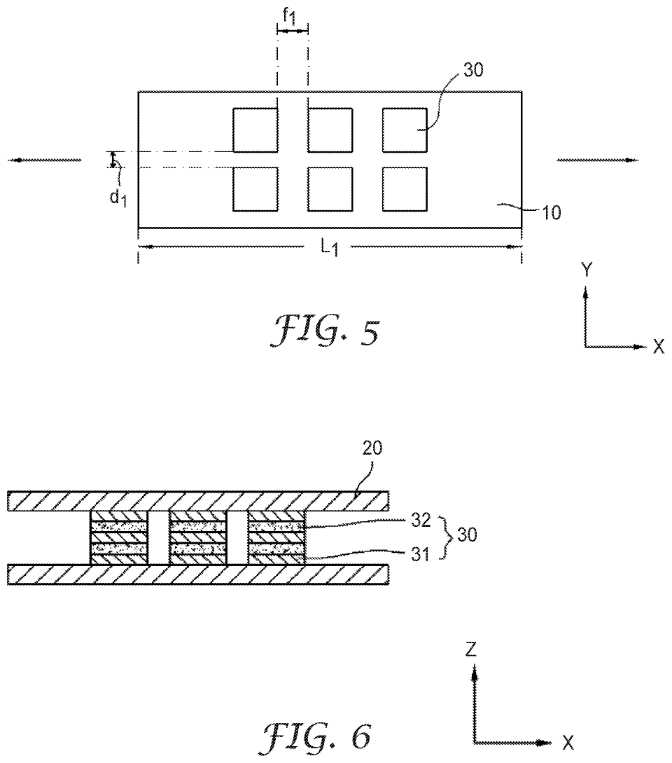

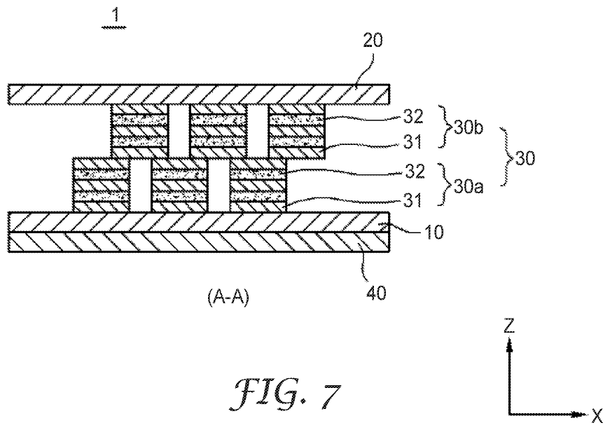

In the above-described example, the plurality of shielding members 30 are formed in a single layer structure by way of an example. However, this is merely an example, and the technical concept of the present disclosures is not limited thereto. Hereinafter, variations of the plurality of shielding members 30 will be described with reference to FIGS. 6 and 7.

FIG. 6 is a cross-sectional view illustrating a variation of the plurality of shielding members of the shielding tape according to an embodiment, and FIG. 7 is a cross-sectional view illustrating another variation of the plurality of shielding members of the shielding tape according to an embodiment.

Referring to FIG. 6, each of the plurality of shielding members 30 may be formed in a multi-layer structure in which a plurality of magnetic substances 31 are stacked one on another. The thickness of the shielding tape 1 may increase due to the shielding member 30 having the structure in which the plurality of magnetic substances 31 are stacked one on another. Therefore, the shielding efficiency of the shielding tape 1 for electromagnetic wave can be enhanced.

The shielding member 30 may be formed by alternately stacking the magnetic substance 31 and an adhesive member 32 one on another. Herein, the adhesive member 32 may be a pressure sensitive adhesive (PSA) which electrically conducts by pressure applied thereto. However, this is merely an example, and any adhesive member that has predetermined electrical conductivity is applicable as the adhesive member 32.

Referring to FIG. 7, the plurality of shielding members 30 may include at least one first shielding member 30a arranged on one surface of the first soft member 10, and at least one second shielding member 30b arranged on one surface of the second soft member 20. The first shielding member 30a and the second shielding member 30b may be formed by alternatively stacking the magnetic substance 31 and the adhesive member 32 one on another, and the at least one first shielding member 30a and the at least one second shielding member 30b may be arranged to overlap each other at least in part.

The following is a list of embodiments of the present disclosure.

Item 1 relates to a shielding tape including a plurality of shielding members discrete from one another on a same plane, wherein, when the shielding tape is stretched in a first direction (lateral direction) which is perpendicular to a thickness direction of the shielding tape, a distance between at least a portion of the shielding members increases, and a distance between the other portion of the shielding members is reduced.

Item 2 relates to the shielding tape, wherein, when a tensile force for stretching the shielding tape in the first direction is removed, a length of the shielding tape in the first direction returns within 110% of an initial length of the shielding tape in the first direction.

Item 3 relates to a shielding tape including a plurality of shielding members discrete from one another on a same plane, wherein, when the shielding tape is stretched in a first direction which is perpendicular to a thickness direction of the shielding tape, a change in relative permeability of the shielding tape stretched in the first direction is less than 10% of relative permeability of the shielding tape before the shielding tape is stretched in the first direction.

Item 4 relates to the shielding tape, wherein the first direction corresponds to a length direction of the shielding tape.

Item 5 relates to a shielding tape including: a first soft member; a second soft member disposed to face the first soft member; and a plurality of shielding members coupled to at least one of the first soft member and the second soft member, and arranged between the first soft member and the second soft member, wherein the plurality of shielding members are arranged to be spaced apart from one another in a first direction which is perpendicular to a thickness direction of the shielding tape.

Item 6 relates to the shielding tape, wherein the plurality of shielding members are spaced apart from one another by a first distance in the first direction, and are spaced apart from one another by a second distance in a second direction intersecting the first direction.

Item 7 relates to the shielding tape, wherein, when an external force is applied to the first soft member and the second soft member in the first direction, the first soft member and the second soft member are stretched in the first direction, such that the first distance increases and the second distance is reduced.

Item 8 relates to the shielding tape, wherein, when the external force applied to the first soft member and the second soft member is removed, the first soft member and the second soft member are contracted, such that the increased first distance is reduced and the reduced second distance increases.

Item 9 relates to the shielding tape, wherein, as a distance between the shielding members is reduced, a frequency blocked by the shielding member is reduced, and, as the distance between the shielding members increases, the frequency blocked by the shielding member increases.

Item 10 relates to the shielding tape, wherein, as a size of a cross section of each of the plurality of shielding members in a direction parallel to the first soft member and the second soft member increases, a frequency blocked by the shielding member is reduced, and, as the size of the cross section of each of the plurality of shielding members in the direction parallel to the first soft member and the second soft member is reduced, the frequency blocked by the shielding member increases.

Item 11 relates to the shielding tape, wherein the plurality of shielding members include magnetic substances stacked one on another.

Item 12 relates to the shielding tape, wherein the stacked magnetic substance has a rectangular shape.

Item 13 relates to the shielding tape, wherein the plurality of shielding members include a first shielding member arranged on one surface of the first soft member, and a second shielding member arranged on one surface of the second soft member, and the at least one first shielding member and the at least one second shielding member overlap each other at least in part.

Item 14 relates to the shielding tape, wherein the first soft member and the second soft member are formed with a rubber material.

Item 15 relates to the shielding tape further including an adhesive layer formed on an outer surface of any one of the first soft member and the second soft member.

Although specific forms of the shielding tape according to embodiments have been described, these are merely examples, and the present disclosure is not limited thereto, and the embodiments should be interpreted as having the widest scope according to the basic concept disclosed in the detailed description. In addition, it is obvious to a person skilled in the art that embodiments disclosed based on the detailed description can be easily changed and deformed, and such changes or deformation belong to the right scope of the present disclosure.

### EXPLANATION OF SIGNS

| | |
|---|---|
| 1: shielding tape | 10: first soft member |
| 20: second soft member | 30: shielding member |
| 30a: first shielding member | 30b: second shielding member |
| 31: magnetic substance | 32: adhesive member |
| 40: adhesive layer | |

What is claimed is:

1. A shielding tape comprising a plurality of shielding members discrete from one another on a same plane,
wherein, when the shielding tape is stretched in a first direction which is perpendicular to a thickness direction of the shielding tape, a distance between at least a portion of the shielding members increases, and a distance between the other portion of the shielding members is reduced.

2. The shielding tape of claim 1, wherein, when a tensile force for stretching the shielding tape in the first direction is removed, a length of the shielding tape in the first direction returns within 110% of an initial length of the shielding tape in the first direction.

3. A shielding tape comprising a plurality of shielding members discrete from one another on a same plane,
wherein, when the shielding tape is stretched in a first direction which is perpendicular to a thickness direction of the shielding tape, a change in relative permeability of the shielding tape stretched in the first direction is less than 10% of relative permeability of the shielding tape before the shielding tape is stretched in the first direction.

4. A shielding tape comprising:
a first soft member;
a second soft member disposed to face the first soft member; and
a plurality of shielding members coupled to at least one of the first soft member and the second soft member, and arranged between the first soft member and the second soft member,
wherein the plurality of shielding members are arranged to be spaced apart from one another in a first direction which is perpendicular to a thickness direction of the shielding tape.

5. The shielding tape of claim 4, wherein the plurality of shielding members are spaced apart from one another by a first distance in the first direction, and are spaced apart from one another by a second distance in a second direction intersecting the first direction, and wherein, when an external force is applied to the first soft member and the second soft member in the first direction, the first soft member and the second soft member are stretched in the first direction, such that the first distance increases and the second distance is reduced.

6. The shielding tape of claim 5, wherein, when the external force applied to the first soft member and the second soft member is removed, the first soft member and the second soft member are contracted, such that the increased first distance is reduced and the reduced second distance increases.

7. The shielding tape of claim 4, wherein, as a distance between the shielding members is reduced, a frequency blocked by the shielding member is reduced, and
wherein, as the distance between the shielding members increases, the frequency blocked by the shielding member increases.

8. The shielding tape of claim 4, wherein, as a size of a cross section of each of the plurality of shielding members in a direction parallel to the first soft member and the second soft member increases, a frequency blocked by the shielding member is reduced, and
wherein, as the size of the cross section of each of the plurality of shielding members in the direction parallel to the first soft member and the second soft member is reduced, the frequency blocked by the shielding member increases.

9. The shielding tape of claim 4, wherein the plurality of shielding members comprise magnetic substances stacked one on another, and wherein the stacked magnetic substance has a rectangular shape.

10. The shielding tape of claim 4, wherein the plurality of shielding members comprise a first shielding member arranged on one surface of the first soft member, and a second shielding member arranged on one surface of the second soft member, and
wherein the at least one first shielding member and the at least one second shielding member overlap each other at least in part.
